(19) United States
(12) Patent Application Publication
(10) Pub. No.: US 2026/0211071 A1
(43) Pub. Date: Jul. 23, 2026

(54) DEEP LEARNING ENABLED CORRECTION OF EDDY CURRENT INDUCED DISTORTIONS IN DIFFUSION MRI

(71) Applicant: Siemens Healthineers AG, Forchheim (DE)

(72) Inventors: Thorsten Feiweier, Poxdorf (DE); Bryan Clifford, Belmont, MA (US); Cornelius Eichner, Fürth (DE); Heiko Meyer, Uttenreuth (DE); Omar Darwish, London (GB); Mahmoud Mostapha, Princeton, NJ (US); Nirmal Janardhanan, Monmouth Junction, NJ (US); Mariappan S. Nadar, Plainsboro, NJ (US); Yahang Li, Plainsboro, NJ (US); Laszlo Lazar, Gheorgheni (RO); Radu Miron, Iasi (RO)

(21) Appl. No.: 19/032,476

(22) Filed: Jan. 21, 2025

(51) Int. Cl. G01R 33/565; G01R 33/563

(52) U.S. Cl. CPC G01R 33/56518; G01R 33/56341

(57) ABSTRACT

Systems and methods for correction of eddy current induced distortions in diffusion MRI. Adjustment scans acquire images with diffusion encodings. A machine learned network computes spatial distortion maps. The spatial distortion maps are used to correct eddy current induced distortions is subsequent acquisitions.

### FIELD

This disclosure relates to medical imaging.

### BACKGROUND

Diffusion-weighted echoplanar imaging (DW-EPI) represents an established technique used for the characterization of pathological tissue changes in clinical magnetic resonance imaging (MRI). This technique requires strong diffusion-encoding gradients but is limited to EPI-typical low pixel bandwidths (BW) of ~10 Hz/pixel along the phase-encoding direction. As a result, eddy current induced spatiotemporal variations of the B0 field may lead to geometric image distortions, deteriorating the diagnostic value.

For diagnostic purposes, data acquired with different diffusion weightings (b-values) and/or diffusion directions are usually jointly evaluated to generate parameter maps (e.g., apparent diffusion coefficient ADC, Trace or fractional anisotropy FA). Unfortunately, image distortions depend on the amplitude and direction of the applied diffusion encoding gradient; in a joint evaluation, corresponding spatial mismatch (geometric distortions) thus leads to reduced precision of parameter estimations.

### SUMMARY

By way of introduction, the preferred embodiments described below include methods, systems, instructions, and/or computer readable media for correction of eddy current induced distortions in diffusion MRI.

In a first aspect, a method for correction of eddy current induced distortions in diffusion MRI, the method comprising: acquiring, using a first adjustment scan, a first set of images with a first diffusion encoding; acquiring, using a second adjustment scan, a second set of images with a second diffusion encoding, the second diffusion encoding different than the first diffusion encoding; estimating, by a machine learning network, a set of spatial distortion maps based on respective pairs of images from the first set of images and the second set of images; and acquiring, using a imaging scan, a third set of images with arbitrary diffusion encoding; and correcting eddy current induced distortions in the third set of images using the set of spatial distortion maps.

In a second aspect, a method for correction of eddy current induced distortions in diffusion MRI, the system comprising: a MRI scanner configured to acquire image data; and a control unit comprising at least a processor and a memory, the control unit configured to instruct the MRI scanner to perform a first adjustment scan to acquire a first set of imaging data, to perform a second adjustment scan to acquire a second set of imaging data, and to perform an imaging procedure on a patient to acquire a third set of imaging data, wherein the control unit is configured, using a machine learning network, to estimate displacements maps from the first set of imaging data and the second set of imaging data and correct the third set of imaging data using at least the displacement maps.

In a third aspect, a non-transitory computer readable storage medium comprising a set of computer-readable instructions stored thereon for correction of eddy current induced distortions in diffusion MRI, the computer-readable instructions which, when executed by at least one processor cause the at least one processor to: estimate, using a machine learning network, a set of spatial distortion maps based on respective pairs of images from a first set of images from a first adjustment scan performed with a first diffusion encoding and a second set of images from a second adjustment scan performed with a second diffusion encoding, the second diffusion encoding different than the first diffusion encoding; and correct eddy current induced distortions in a third set of images using the set of spatial distortion maps.

Any one or more of the aspects described above may be used alone or in combination. These and other aspects, features and advantages will become apparent from the following detailed description of preferred embodiments, which is to be read in connection with the accompanying drawings. The present invention is defined by the following claims, and nothing in this section should be taken as a limitation on those claims. Further aspects and advantages of the invention are discussed below in conjunction with the preferred embodiments and may be later claimed independently or in combination.

### BRIEF DESCRIPTION OF THE DRAWINGS

The components and the figures are not necessarily to scale, emphasis instead being placed upon illustrating the principles of the embodiments. Moreover, in the figures, like reference numerals designate corresponding parts throughout the different views.

FIG. 1 depicts an example system for correction of eddy current induced distortions in diffusion MRI according to an embodiment.

FIG. 2 depicts an example workflow for correction of eddy current induced distortions in diffusion MRI according to an embodiment.

FIG. 3 depicts an example adjustment acquisition according to an embodiment.

FIG. 4 depicts an example neural network for correction of eddy current induced distortions in diffusion MRI according to an embodiment.

FIG. 5 depicts an example convolutional neural network correction of eddy current induced distortions in diffusion MRI according to an embodiment.

FIG. 6 depicts an example method for correction of eddy current induced distortions in diffusion MRI according to an embodiment.

FIG. 7 depicts an example U-net architecture for correction of eddy current induced distortions in diffusion MRI according to an embodiment.

### DETAILED DESCRIPTION

Embodiments described herein provide systems and methods that provide a robust and fast reduction of spatial mismatch due to eddy currents induced by diffusion encoding gradients.

Diffusion-weighted imaging (DWI) and diffusion-tensor imaging (DTI) are non-invasive MRI techniques with broad clinical applications. Unfortunately, diffusion imaging suffers from substantial artifacts such as those caused by eddy currents that are induced in conducting structures of the magnet bore by gradient switching. Diffusion imaging is particularly prone to eddy current artifacts due to relatively long EPI (echo planar imaging) readouts combined with strong diffusion sensitizing gradients. Unlike static field inhomogeneities, eddy currents do not remain constant over diffusion encoding directions. Rather, they vary depending upon the magnitude and direction of the applied diffusion gradients. This leads to spatial misregistration and inconsistency between uncorrected images obtained with different diffusion-encoding directions or b-values. Ignoring eddy currents in the image reconstruction results in bulk object shifts and deformations, as well as signal dropouts.

In particular, EPI distortion may occur where eddy currents induced by diffusion-weighting MPG (motion probing gradients) produce large field perturbations, where distortion amplitude(s) and direction(s) are different for each b vector, and/or where misalignment of images caused by eddy currents results in poor quality ADC and DTI maps, as well as other maps generated on the basis of at least two images with different diffusion-weighting MPG.

A number of techniques have been tried to address and/or correct the problems resulting from eddy currents. In an example, an image-based technique assumes a limited set of transformations (affine, i.e., translation, shear, scaling) and uses an extensive search algorithm (utilizing cross-correlation with a b=0 reference image as a similarity measure) to identify the corresponding correction factors. Images with very high b-values (which may exhibit a different contrast which cross-correlation does not properly account for) may be corrected by linear extrapolation of the correction factors. However, this technique has drawbacks such as not considering the impact of higher-order eddy currents, requiring imaging protocols which include reasonably low b-values, limited precision due to contrast variation between distorted and reference image, and requiring high computational demand (resulting from the computational complexity of the aforementioned extensive search algorithm), which increases with the number of directions.

Another technique acquires two images with the same b-value but inverted polarity of the diffusion encoding gradients. Both images exhibit similar contrast, but eddy current induced distortions are inverted and may thus be estimated using an algorithm similar to that described above. Again, similar to the technique described above, only first order (affine) transformations are considered. This technique also has additional drawbacks such as not considering the impact of higher-order eddy currents, requiring an acquisition of two images for each b-value and diffusion direction, i.e., increased scan time, limited precision due to low signal-to-noise ratio (SNR) of high b-value images, and high computational demand (resulting from the computational complexity of the aforementioned extensive search algorithm), which increases with the number of directions.

Another technique builds on a similar principle where the diffusion contrast is modelled as a Gaussian process, thereby reducing the need for strict inversion of diffusion gradients. This allows to estimate contrasts by interpolation between other close directions. However, this process requires a very computationally demanding and time consuming reconstruction and provides limited precision due to SNR of high b-value images.

Embodiments described herein solve these issues by providing a deep learning enabled estimation of distortion fields combined with a linear superposition model. The deep learning component enables a robust and fast estimation of distortion fields with high spatial fidelity and the linear superposition model reduces the amount of required data and thus the total scan duration.

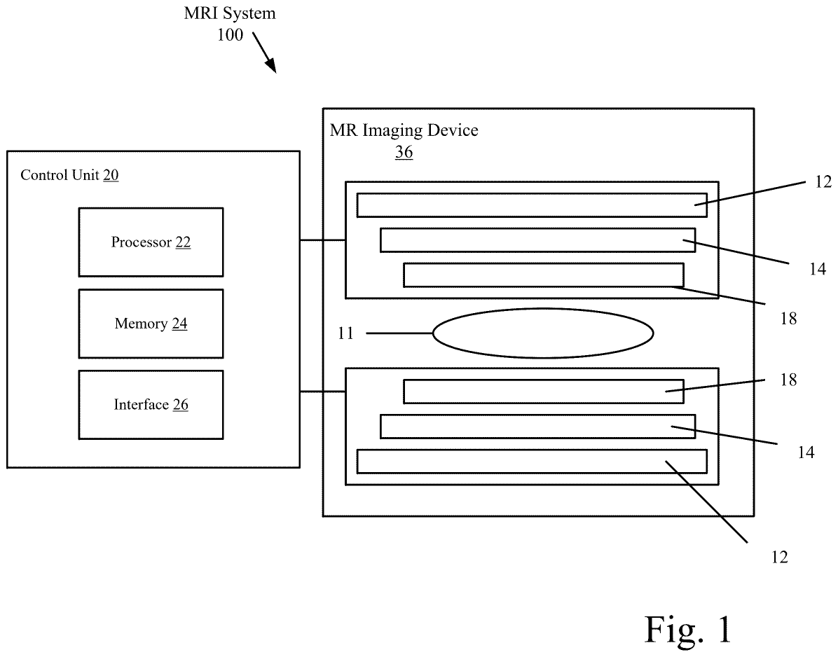

FIG. 1 depicts an example MR system 100 for correction of eddy current induced distortions in diffusion MRI. The MR system 100 includes an MR scanner 36 or system, a computer based on data obtained by MR scanning, a server, or another processor 22. The MR imaging device 36 is only exemplary, and a variety of MR scanning systems may be used to collect the MR data. The MR imaging device 36 (also referred to as a MR scanner or image scanner) is configured to scan a patient 11. The scan provides scan data in a scan domain. The MR imaging device 36 scans a patient 11 to provide k-space measurements (measurements in the frequency domain). A plurality of dedicated adjustment scans that acquire data with the diffusion encodings G_{x/y/z,A/B}(t) as described below are performed. The adjustment scan data is used to estimate distortion fields that may be used for image correction of subsequent scans.

The MR system 100 further includes a control unit 20 configured to process the MR signals and estimate the distortion fields. The control unit may further generate and/or correct images of the object or patient 11 for display to an operator. The control unit 20 includes a processor 22 that is configured to execute instructions, or the method described herein. The control unit 20 may store the MR signals and images in a memory 24 for later processing or viewing. The control unit 20 may include a display 26 for presentation of images to an operator.

In the MR system 100, magnetic coils 12 create a static base or main magnetic field B0 in the body of patient 11 or an object positioned on a table and imaged. Within the magnet system are gradient coils 14 for producing position dependent magnetic field gradients superimposed on the static magnetic field. Gradient coils 14, in response to gradient signals supplied thereto by a gradient and control unit 20, produce position dependent and shimmed magnetic field gradients in three orthogonal directions and generate magnetic field pulse sequences. The shimmed gradients compensate for inhomogeneity and variability in an MR imaging device magnetic field resulting from patient anatomical variation and other sources.

The control unit 20 may include a RF (radio frequency) module that provides RF pulse signals to RF coil 18. The RF coil 18 produces magnetic field pulses that rotate the spins of the protons in the imaged body of the patient 11 by ninety degrees or by one hundred and eighty degrees for so-called “spin echo” imaging, or by angles less than or equal to 90 degrees for “gradient echo” imaging. Gradient and shim coil control modules in conjunction with RF module, as directed by control unit 20, control slice-selection, MPG, phase-encoding, readout gradient magnetic fields, radio frequency transmission, and magnetic resonance signal detection, to acquire magnetic resonance signals representing planar slices of the patient 11.

In response to applied RF pulse signals, the RF coil 18 receives MR signals, e.g., signals from the excited protons within the body as the protons return to an equilibrium position established by the static and gradient magnetic fields. The MR signals are detected and processed by a detector within the RF module and the control unit 20 to provide an MR dataset to a processor 22 for processing into an image. In some embodiments, the processor 22 is located in the control unit 20, in other embodiments, the processor 22 is located remotely. A two or three-dimensional k-space storage array of individual data elements in a memory 24 of the control unit 20 stores corresponding individual frequency components including an MR dataset. The k-space array of individual data elements includes a designated center, and individual data elements individually include a radius to the designated center.

A magnetic field generator (including coils 12, 14 and 18) generates a magnetic field for use in acquiring multiple individual frequency components corresponding to individual data elements in the storage array. The individual frequency components are successively acquired. A storage processor in the control unit 20 stores individual frequency components acquired using the magnetic field in corresponding individual data elements in the array. The row and/or column of corresponding individual data elements alternately increases and decreases as multiple sequential individual frequency components are acquired. The magnetic field generator acquires individual frequency components in an order corresponding to a sequence of substantially adjacent individual data elements in the array, and magnetic field gradient change between successively acquired frequency components is substantially minimized. The control unit 20 may use information stored in an internal database to process the detected MR signals in a coordinated manner to generate images of a selected slice(s) of the body (e.g., using the image data processor) and adjusts other parameters of the system 100. The stored information includes a predetermined pulse sequence of an imaging protocol and a magnetic field gradient and strength data as well as data indicating timing, orientation, and spatial volume of gradient magnetic fields to be applied in imaging.

The MR imaging device 36 is configured by the imaging protocol to scan a region of a patient 11. For example, in MR, such protocols for scanning a patient 11 for a given examination or appointment include diffusion-weighted imaging (acquisition of multiple b-values, averages, and/or diffusion directions), and other imaging procedures which depict the anatomy with different contrasts.

For an imaging procedure to scan the patient 11, changing magnetic gradient fields may cause, in accordance with Lenz's law, an unwanted opposing magnetic field (generated by eddy currents induced in conducting structures). This is generally modeled as an exponential decaying function proportional to a change in amplitude of the gradient field (ΔG). Eddy currents may be modeled using spherical harmonic polynomials where there are: a zeroth order term (spatially invariant field); first order terms (linear field gradients), including “self-terms”: ΔGX causes a field which exhibits a non-constant, non-linear dependence on the X-, Y-, and Z-position. Eddy currents are often affected by subtle MRI system details such as gradient tube manufacturing imperfections, gradient tube installation imperfections, cryostat design, cryogen (helium) levels, shield design and the like. Despite advances in magnetic gradient coil driver hardware, including gradient pre-emphasis and shielded coil designs, residual eddy current fields persist in current MR scanners. For most applications, residual eddy current fields have a negligible effect on image quality. However, some sequence applications like Diffusion Weighted Echo Planar Imaging (DW-EPI) are highly sensitive to these eddy fields.

In general, the eddy current field, induced by the diffusion encoding gradient Gᵢ(t), is persistent during the EPI module and exhibits a spatiotemporal characteristic Eᵢ(r,t). However, when focusing on geometric distortions, only considering temporal averages Eᵢ(r) of long-lasting eddy currents may be sufficient for image correction. In an embodiment described herein, images are assumed to be encoded with diffusion gradient shapes Gᵢ(t)=f(t) Rᵢ Gᵢ=f(t) aᵢ Rᵢ (1, 0, 0). (Note: bold symbols represent vectors, underlined bold symbols matrices. For the sake of simplicity, physical xyz-coordinates that are aligned with the axes of the gradient coil are used). This representation also includes arbitrary encoding shapes f(t). The rotation matrix Rᵢ describes acquisition-specific axis assignments (i.e., diffusion directions) while the scale factor aᵢ relates to acquisition specific diffusion weightings.

Assuming an independent superposition of eddy current fields generated on each axis as well as a linear scaling with the amplitude of the generating gradients, the spatial characteristics may be decomposed as follows: Eᵢ(r)=aᵢ (Rᵢ êₓ Êₓ(r)+Rᵢ ê_{y} Ê_{y}(r)+Rᵢ ê_{z} Ê_{z}(r)) where Ê_{x/y/z}(r) represent the eddy current fields induced by a unit gradient along the corresponding axis ê_{x/y/z}. The characterization of the reference eddy current fields Ê_{x/y/z}(r) is thus sufficient as used herein to obtain the information required to correct images acquired with arbitrary diffusion scaling and orientation.

In an embodiment, the processor 22 is configured to apply a deep learning (machine learning) technique in order to characterize/compute the reference eddy current fields. The processor 22 is a general processor, digital signal processor, three-dimensional data processor, graphics processing unit, application specific integrated circuit, field programmable gate array, artificial intelligence processor, digital circuit, analog circuit, combinations thereof, or another now known or later developed device for applying a machine learning model and correcting images. The processor 22 is a single device, a plurality of devices, or a network. For more than one device, parallel or sequential division of processing may be used. Different devices making up the processor 22 may perform different functions, such as reconstructing by one device and volume rendering by another device. In one embodiment, the processor 22 is a control processor or other processor of the MR system 100. Other processors of the MR system 100 or external to the MR system 100 may be used. The processor 22 is configured by software, firmware, and/or hardware to reconstruct. The instructions for implementing the processes, methods, and/or techniques discussed herein are provided on non-transitory computer-readable storage media or memories, such as a cache, buffer, RAM, removable media, hard drive, or other computer readable storage media. The instructions are executable by the processor 22 or another processor. Computer readable storage media include various types of volatile and nonvolatile storage media. The functions, acts or tasks illustrated in the figures or described herein are executed in response to one or more sets of instructions stored in or on computer readable storage media. The functions, acts or tasks are independent of the instructions set, storage media, processor or processing strategy and may be performed by software, hardware, integrated circuits, firmware, micro code, and the like, operating alone or in combination. In one embodiment, the instructions are stored on a removable media device for reading by local or remote systems. In other embodiments, the instructions are stored in a remote location for transfer through a computer network. In yet other embodiments, the instructions are stored within a given computer, CPU, GPU, or system. Because some of the constituent system components and method steps depicted in the accompanying figures may be implemented in software, the actual connections between the system components (or the process steps) may differ depending upon the manner in which the present embodiments are programmed.

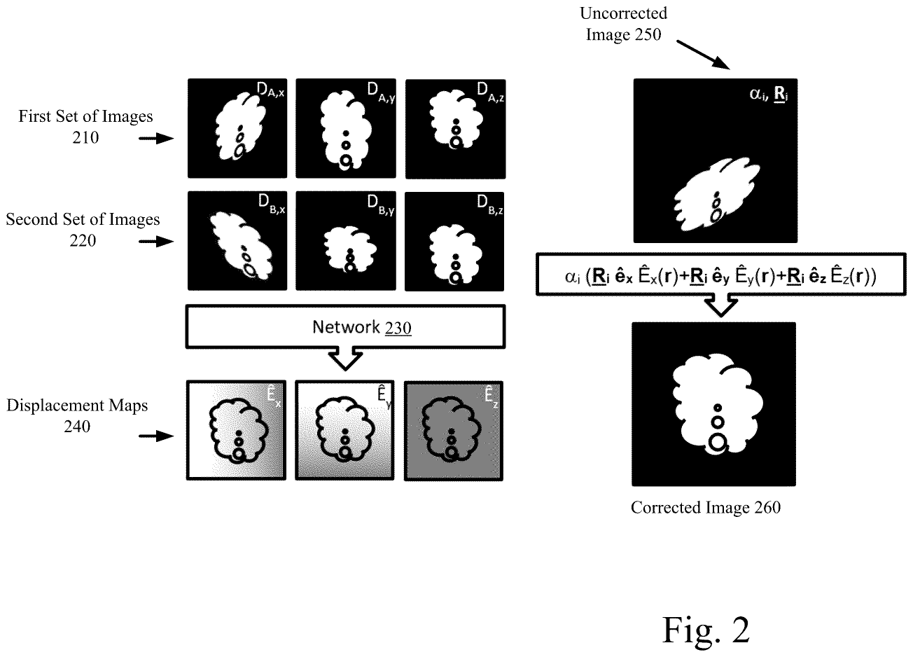

FIG. 2 depicts an example workflow for correction of eddy current induced distortions in diffusion MRI. Using six adjustment scans, a deep learning algorithm is used to characterize the eddy current fields. Based on this characterization, corrections are applied to images acquired with arbitrary diffusion encoding. In an embodiment, the processor 22 is configured to acquire a set of first images 210 with a first diffusion encoding, acquire a set of second images 220 with a different diffusion encoding, estimate a set of spatial distortion maps/displacement maps 240 based on the first set of images 210 and the second set of images 220 using a machine learning network 230, and use the displacement maps 240 to correct a third set of images 250 generating a corrected image(s) 260.

As depicted in FIG. 2, in an embodiment, pairs of images from the sets of images, i.e., image A and image B with different diffusion scaling but identical shapes are acquired, i.e., with respective encoding gradients:

$$\begin{matrix}{G}_{x , A} ( t ) = f ( t ) {a}_{A , x} {\underline{R}}_{x} ( 1 , 0 , 0 ) = f ( t ) {a}_{A , x} {\hat{e}}_{x} , & {G}_{x , B} ( t ) = f ( t ) {a}_{B , x} {\underline{R}}_{x} ( 1 , 0 , 0 ) = f ( t ) {a}_{B , x} {\hat{e}}_{x} \\ {G}_{y , A} ( t ) = f ( t ) {a}_{A , y} {\underline{R}}_{y} ( 1 , 0 , 0 ) = f ( t ) {a}_{A , y} {\hat{e}}_{y} , & {G}_{y , B} ( t ) = f ( t ) {a}_{B , y} {\underline{R}}_{y} ( 1 , 0 , 0 ) = f ( t ) {a}_{B , y} {\hat{e}}_{y} \\ {G}_{z , A} ( t ) = f ( t ) {a}_{A , z} {\underline{R}}_{z} ( 1 , 0 , 0 ) = f ( t ) {a}_{A , z} {\hat{e}}_{z} , & {G}_{z , B} ( t ) = f ( t ) {a}_{B , z} {\underline{R}}_{z} ( 1 , 0 , 0 ) = f ( t ) {a}_{B , z} {\hat{e}}_{z}\end{matrix}$$

yielding eddy current fields E_{x/y/z,A}(r)=a_{A,x/y/z} Ê_{x/y/z}(r) and E_{x/y/z,B}(r)=a_{B,x/y/z} Ê_{x/y/z}(r). Using a_{B,x/y/z}=−a_{A,x/y/z} yields images with identical contrast but inverted distortions.

While using axis-specific scaling factors is possible without any restrictions, in an embodiment, identical values a_{A,x}=a_{A,y}=a_{A,z}=a_{A} and a_{B,x}=a_{B,y}=a_{B,z}=a_{B} are used. choice. In addition, while using |a_{B}|≠|a_{A}| may be possible, this may affect image contrast, requiring a more complex network architecture, increased training effort, and potentially longer reconstruction time. Further, while characterizing eddy currents in a different coordinate system may be possible, embodiments described below use physical xyz-coordinates aligned with the gradient axes.

Using a pair of distorted images D_{x/y/z,A}(r) and D_{x/y/z,B}(r) as an input, deep learning techniques generate displacement maps M_{x/y/z}(r) which characterize a transformation D_{x/y/z,A}(r)->D_{x/y/z,B}(r) (or vice versa). The processor 22 may implement, for example, an image to image network to generate the displacement maps 240 as described below. In EPI, displacements Δr along the phase-encoding direction scale linearly with the field deviation Δf=BW Δr: thus, the generated M_{x/y/z}(r) is directly linked to the underlying ΔE_{x/y/z}(r)=(E_{x/y/z,A}(r)−E_{x/y/z,B}(r))=BW M_{x/y/z}(r). Note that this equation assumes that M is specified in units of pixels and BW is specified in units of T/pixel. Conversion to the more commonly used BW in units of Hz/pixel requires multiplication by γ/(2π). With this, it is possible to obtain the required reference eddy current fields Ê_{x/y/z}(r)=(E_{x/y/z,A}(r)−E_{x/y/z,B}(r))/(a_{A}−a_{B})=BW M_{x/y/z}(r)/(a_{A}−a_{B}) or, using the suggested choice a_{B}=−a_{A} (ensuring identical image contrast), Ê_{x/y/z}(r)=(E_{x/y/z,A}(r)−E_{x/y/z,B}(r))/(2 a_{A})=BW M_{x/y/z}(r)/(2 a_{A})

Once Ê_{x/y/z}(r) are known the processor 22 obtains an estimate of the eddy current fields for any rotation and/or scaling of the diffusion gradients. Using the corresponding displacement maps 240, distortions may be corrected using, for example, an image transformation employing nearest-neighbor, (bi-)linear, (bi-)cubic, or one- or two-dimensional spline interpolation, respectively. The corrections may not only consider corrections of image geometry, but also of accompanying local intensity variations (e.g., using a Jacobian determinant). Once available, the corrections may not only get applied to magnitude images, but also to phase images, real- or imaginary-part images, or any kind of combinations.

In an embodiment, full control over the axis-specific scaling factors may be performed without restrictions. The optimal set of scaling parameters may be learned for a given gradient system or device and stored in advance of a specific acquisition such that the error in the estimated eddy current fields Ê_{x/y/z}(r) is minimized. For example, with a_{B,x}/y/z=−a_{A,x/y/}z=−aᵢ and denoting a single axis of one of x, y, or z as “i”, and position rⱼ, and the corresponding estimate of the eddy current field as Êⱼᵢ, then the error in the estimate, as a function of error in the estimated displacement field at location rⱼ, eᵢⱼ, may be shown to equal: Error in Êᵢⱼ=BW(eᵢⱼ(aᵢ)/2 aᵢ), where the dependence of eᵢⱼ on the value of aᵢ has been made explicit. Then the optimal value of aᵢ may therefore be given by: aᵢ*=arg minₐ Σⱼ|eᵢⱼ(a)/a|, Or more generally, the set of optimal axis-specific scaling factors may be learned jointly, e.g., {aᵢ*}ᵢ=arg min_{{ai}} Σⱼ|eᵢⱼ(aᵢ)/aᵢ|. In the above optimizations, the loss, i.e., sum over absolute errors, may be replaced by various other forms of loss functions, e.g., sum of squared errors, sum of log absolute errors, etc. . . . .

In practice, the error in the estimated displacement field may vary due to experimental factors, such as SNR and image intensity, e.g., in regions of low image intensity, the displacement estimates may be very noisy. Furthermore, the error may vary as a function of the axis-specific scaling factor (as made explicit in the above example): larger scaling factors may lead to increased reduction of signal intensity, which may lead to increased noise in displacement estimates. In general, aᵢ* may be a “sweet spot” for the scaling factor which gives the best tradeoff between eddy current sensitivity and noise.

In an embodiment, if more than two diffusion directions are acquired in one measurement (e.g., three orthogonal directions for generating trace-weighted images, or at least six non-colinear directions for a diffusion tensor estimation), a complete characterization of the eddy current fields is possible. For this purpose, the imaging scans may be accompanied (for example, preceded) by a plurality of dedicated adjustment scans which acquire data with the diffusion encodings G_{x/y/z,A/B}(t) as outlined above. The following considerations apply: for each axis, the two adjustment scans are acquired immediately after each other (e.g., +x/−x/+y/−y/+z/−z). This reduces the impact of subject motion on the eddy current field estimations. In case of low SNR, each pair of scans may be repeated multiple times and the estimation uses averaged adjustment scans. As an alternative, denoising techniques, for example iterative denoising or deep learning based methods may be applied to enhance SNR. As an alternative, eddy current maps may be estimated for each repetition separately, and then the results averaged.

The impact of motion may also be addressed by applying a (rigid body) registration of each image pair before estimating the eddy current fields. This may be performed using a separate neural network, or the additional rigid body parameters may be included in the original estimation, i.e., the network may learn to estimate both rigid motion and eddy current displacements.

In another embodiment, three adjustment scans are acquired for each axis, i.e., +x/−x/+x, +y/−y/+y, +z/−z/+z. By independently estimating the eddy current fields based on the pairs +x/−x and −x/+x etc., the impact of motion may be mitigated. Networks may also be trained on all three adjustment scans, for example by augmenting the training data with (potentially artificial) subject motion, the network may learn to separate the desired eddy current fields.

The diffusion weighting of the adjustment scans may be selected such as to obtain a reasonable compromise between SNR (signal attenuates with higher b-value) and the amount of distortions (reduced distortions with lower b-value). For instance, the adjustment scans may utilize a gradient amplitude not higher than 50% of the maximum per-axis gradient amplitude used in the imaging scans.

A potential extension of the technique may entail multi echo acquisitions. The decay of eddy currents may lead to some echoes being differently influenced than others: this may be captured by characterizing eddy current induced distortions for each echo as outlined above.

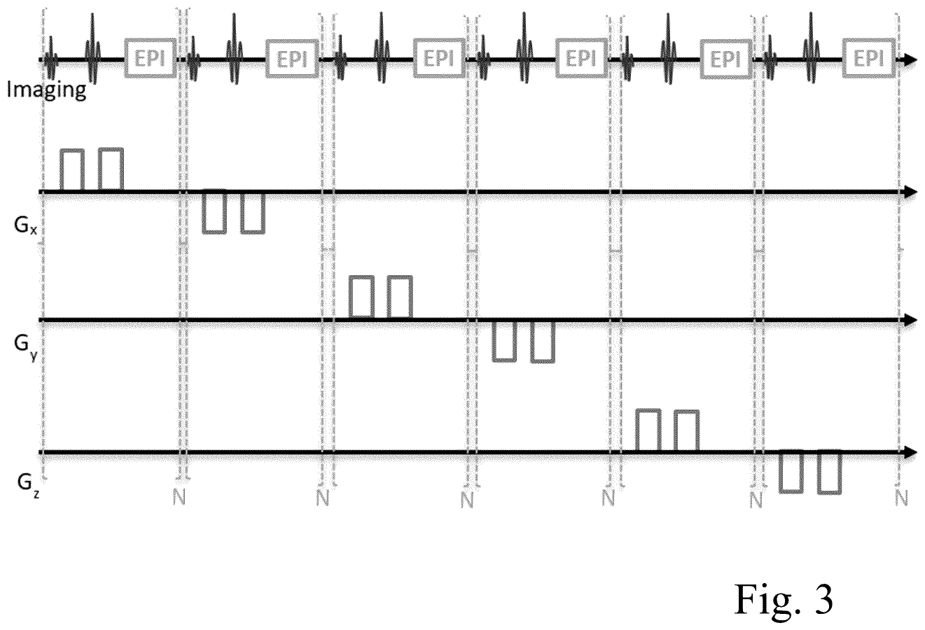

FIG. 3 depicts an example of a characterization of the eddy current fields for a “Stejskal-Tanner” diffusion encoding using six adjustment scans. The repetitions indicated by the brackets with a repetition factor N may refer to averaging and/or the acquisition of multiple slices. Acquisition order may be sequential (as shown here) or any kind of interleaved pattern. If only one or two diffusion directions are acquired in one measurement (e.g., a single diagonal diffusion encoding direction), an adapted characterization of eddy current fields enables faster data acquisition. In this case, one may consider acquiring adjustment scans along the same directions as used in the imaging scans.

Rather than immediately applying a distortion correction based on the estimated eddy current fields, one may consider storing the assigned distortion maps and jointly correcting multiple sources of distortions, e.g., originating from susceptibility variations, concomitant fields and/or gradient non-linearities. This reduces possible loss of precision from repeated data interpolation.

In an embodiment, the processor 22 is configured to implement one or more machine learning networks 230 using deep learning techniques for generating the displacement maps 240, performing the correction method, registering images, etc. In particular, the processor 22 may use an image to image network(s) for generating a displacement map. The image to image network architecture/weights/configuration may be stored the memory 24. In general, a trained machine learning network 230 mimics cognitive functions that humans associate with other human minds. In particular, by training based on training data the machine learning network 230 is able to adapt to new circumstances and to detect and extrapolate patterns. Another term for “trained machine learning network” is “trained function”. In general, parameters of a machine learning network 230 may be adapted by means of training. In particular, supervised training, semi-supervised training, unsupervised training, reinforcement learning and/or active learning may be used. Furthermore, representation learning (an alternative term is “feature learning”) may be used. In particular, the parameters of the machine learning networks 230 may be adapted iteratively by several steps of training. In particular, within the training a certain cost function may be minimized. In particular, within the training of a neural network the backpropagation algorithm may be used. In particular, a machine learning network 230 may comprise a neural network, a support vector machine, a decision tree and/or a Bayesian network, and/or the machine learning network 230 may be based on k-means clustering, Q-learning, genetic algorithms and/or association rules. In an embodiment, the neural network may be a deep neural network, a convolutional neural network, or a convolutional deep neural network. Furthermore, a neural network may be an adversarial network, a deep adversarial network and/or a generative adversarial network. In particular, the network is an image to image network in that it inputs image(s) and outputs image (g).

Any type of suitable network may be used for inputting the sets of images and outputting a displacement map. The network(s) may be defined as a plurality of sequential feature units or layers. Sequential is used to indicate the general flow of output feature values from one layer to input to a next layer. The information from the next layer is fed to a next layer, and so on until the final output. The layers may only feed forward or may be bi-directional, including some feedback to a previous layer. The nodes of each layer or unit may connect with all or only a sub-set of nodes of a previous and/or subsequent layer or unit. Skip connections may be used, such as a layer outputting to the sequentially next layer as well as other layers. Rather than pre-programming the features and trying to relate the features to attributes, the deep architecture is defined to learn the features at different levels of abstraction the input data. The features are learned to reconstruct lower level features (i.e., features at a more abstract or compressed level). For example, features for generating a fused image or higher resolution image are learned. For a next unit, features for reconstructing the features of the previous unit are learned, providing more abstraction. Each node of the unit represents a feature. Different units are provided for learning different features.

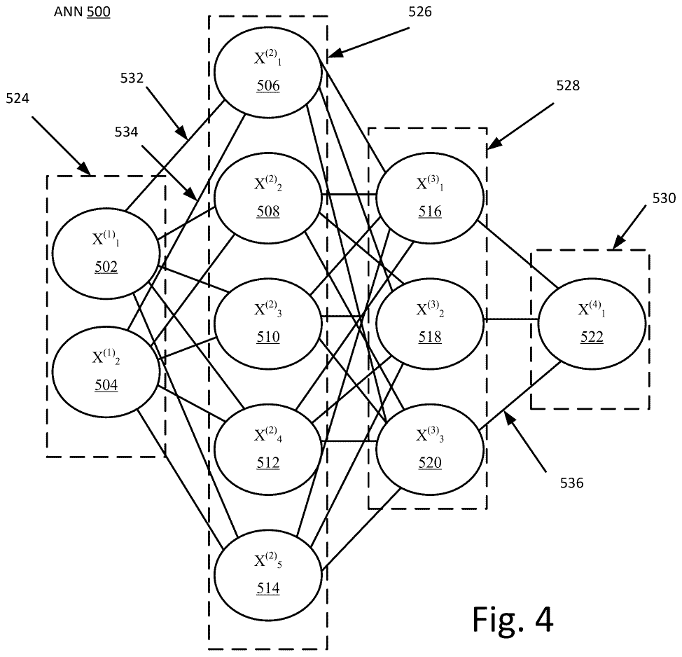

Various units or layers may be used, such as convolutional, pooling (e.g., max-pooling), deconvolutional, fully connected, or other types of layers. Within a unit or layer, any number of nodes is provided. For example, 100 nodes are provided. Later or subsequent units may have more, fewer, or the same number of nodes. In general, for convolution, subsequent units have more abstraction. FIG. 4 shows an embodiment of an artificial neural network (ANN) 500, in accordance with one or more embodiments. Alternative terms for “artificial neural network” are “neural network”, “artificial neural net” or “neural net”. The artificial neural network 500 may be used in part in, for example, the one or more machine learning (deep learning) based networks utilized for generating the displacement map, performing correction, registering images, etc.

The artificial neural network 500 includes nodes 502-522 and edges 532, 534, . . . , 536, wherein each edge 532, 534, . . . , 536 is a directed connection from a first node 502-522 to a second node 502-522. In general, the first node 502-522 and the second node 502-522 are different nodes 502-522, it is also possible that the first node 502-522 and the second node 502-522 are identical. For example, in FIG. 4, the edge 532 is a directed connection from the node 502 to the node 506, and the edge 534 is a directed connection from the node 504 to the node 506. An edge 532, 534, . . . , 536 from a first node 502-522 to a second node 502-522 is also denoted as “ingoing edge” for the second node 502-522 and as “outgoing edge” for the first node 502-522.

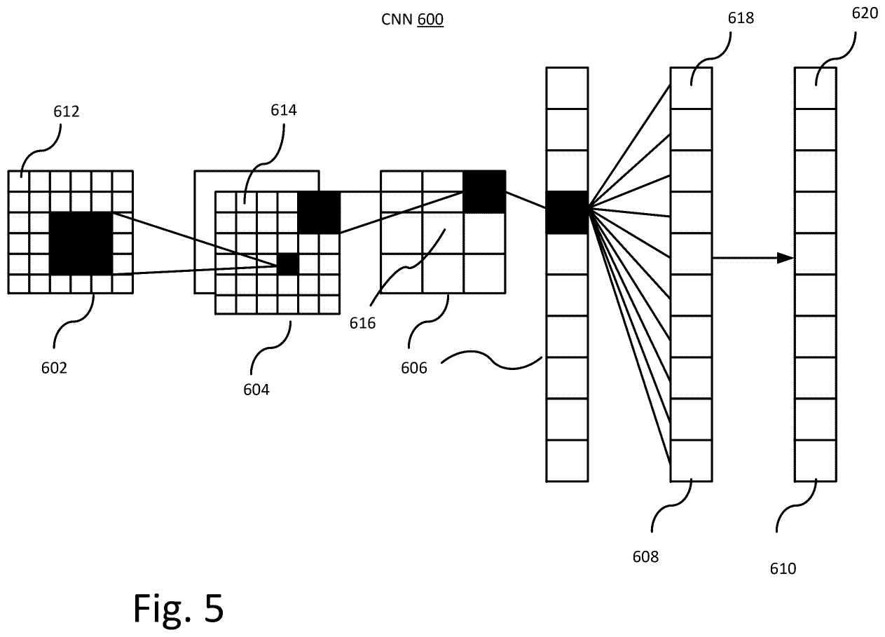

In this embodiment, the nodes 502-522 of the artificial neural network 500 may be arranged in layers 524-530, wherein the layers may include an intrinsic order introduced by the edges 532, 534, . . . , 536 between the nodes 502-522. In particular, edges 532, 534, . . . , 536 may exist only between neighboring layers of nodes. In the embodiment shown in FIG. 5, there is an input layer 524 including only nodes 502 and 504 without an incoming edge, an output layer 530 including only node 522 without outgoing edges, and hidden layers 526, 528 in-between the input layer 524 and the output layer 530. In general, the number of hidden layers 526, 528 may be chosen arbitrarily. The number of nodes 502 and 504 within the input layer 524 usually relates to the number of input values of the neural network 500, and the number of nodes 522 within the output layer 530 usually relates to the number of output values of the neural network 500.

In particular, a (real) number may be assigned as a value to every node 502-522 of the neural network 500. Here, x⁽ⁿ⁾ᵢ denotes the value of the i-th node 502-522 of the n-th layer 524-530. The values of the nodes 502-522 of the input layer 524 are equivalent to the input values of the neural network 500, the value of the node 522 of the output layer 530 is equivalent to the output value of the neural network 500. Furthermore, each edge 532, 534, . . . , 536 may include a weight being a real number, in particular, the weight is a real number . . . , within the interval [−1, 1] or within the interval [0, 1]. Here, w^{(m,n)}_{i,j} denotes the weight of the edge between the i-th node 502-522 of the m-th layer 524-530 and the j-th node 502-522 of the n-th layer 524-530. Furthermore, the abbreviation w⁽ⁿ⁾_{i,j} is defined for the weight w^{(n,n+1)}_{i,j}.

In particular, to calculate the output values of the neural network 500, the input values are propagated through the neural network. In particular, the values of the nodes 502-522 of the (n+1)-th layer 524-530 may be calculated based on the values of the nodes 502-522 of the n-th layer 524-530 by:

$${x}_{j}^{( n + 1 )} = f ( {Σ}_{i} {x}_{i}^{( n )} \cdot {w}_{I , j}^{( n )} ) .$$

Herein, the function f is a transfer function (another term is “activation function”). Known transfer functions are step functions, sigmoid function (e.g. the logistic function, the generalized logistic function, the hyperbolic tangent, the Arctangent function, the error function, the smoothstep function) or rectifier functions. The transfer function is mainly used for normalization purposes.

In particular, the values are propagated layer-wise through the neural network, wherein values of the input layer 524 are given by the input of the neural network 500, wherein values of the first hidden layer 526 may be calculated based on the values of the input layer 524 of the neural network, wherein values of the second hidden layer 528 may be calculated based in the values of the first hidden layer 526, etc.

In order to set the values w^{(m,n)}_{i,j} for the edges, the neural network 500 has to be trained using training data. In particular, training data includes training input data and training output data (denoted as tᵢ). For a training step, the neural network 500 is applied to the training input data to generate calculated output data. In particular, the training data and the calculated output data include a number of values, said number being equal with the number of nodes of the output layer.

In particular, a comparison between the calculated output data and the training data is used to recursively adapt the weights within the neural network 500 (backpropagation algorithm). In particular, the weights are changed according to

$${w}^{{′ ( n )}_{i , j}} = {w}^{{( n )}_{i , j}} - γ \cdot {δ}^{{( n )}_{j}} \cdot {x}^{{( n )}_{i}}$$

wherein γ is a learning rate, and the numbers δ⁽ⁿ⁾ⱼ may be recursively calculated as

$${δ}_{j}^{( n )} = ( {Σ}_{k} {δ}_{k}^{( n + 1 )} \cdot {w}^{{( n )}_{i , j}} ) \cdot {f}^{′} ( {Σ}_{i} {x}^{{( n )}_{j}} \cdot {w}^{{( n )}_{i , j}} )$$

based on δ⁽ⁿ⁺¹⁾ⱼ, if the (n+1)-th layer is not the output layer, and

$${δ}_{j}^{( n )} = ( {x}^{{( n + 1 )}_{j}} - {t}^{{( n + 1 )}_{j}} ) \cdot {f}^{′} ( {Σ}_{i} {x}^{{( n )}_{j}} \cdot {w}^{{( n )}_{i , j}} )$$

if the (n+1)-th layer is the output layer 530, wherein f′ is the first derivative of the activation function, and t⁽ⁿ⁺¹⁾ⱼ is the comparison training value for the j-th node of the output layer 530.

FIG. 5 shows an example convolutional neural network (CNN) 600, in accordance with one or more embodiments. Machine learning networks 230 described herein, such as, e.g., the network 300 for generating displacement maps 240, correcting an image, registering images, etc. may be implemented using the convolutional neural network 600. In the embodiment shown in FIG. 5 the convolutional neural network includes 600 an input layer 602, a convolutional layer 604, a pooling layer 606, a fully connected layer 608, and an output layer 610. Alternatively, the convolutional neural network 600 may include several convolutional layers 604, several pooling layers 606, and several fully connected layers 608, as well as other types of layers. The order of the layers may be chosen arbitrarily, usually fully connected layers 608 are used as the last layers before the output layer 610.

In particular, within a convolutional neural network 600, the nodes 612-620 of one layer 602-610 may be considered to be arranged as a d-dimensional matrix or as a d-dimensional image. In particular, in the two-dimensional case the value of the node 612-620 indexed with i and j in the n-th layer 602-610 may be denoted as x⁽ⁿ⁾_{[i,j]}. However, the arrangement of the nodes 612-620 of one layer 602-610 does not have an effect on the calculations executed within the convolutional neural network 600 as such, since these are given solely by the structure and the weights of the edges.

In particular, a convolutional layer 604 is characterized by the structure and the weights of the incoming edges forming a convolution operation based on a certain number of kernels. In particular, the structure and the weights of the incoming edges are chosen such that the values x⁽ⁿ⁾ₖ of the nodes 614 of the convolutional layer 604 are calculated as a convolution x⁽ⁿ⁾ₖ=Kₖ*x⁽ⁿ⁻¹⁾ based on the values x⁽ⁿ⁻¹⁾ of the nodes 612 of the preceding layer 602, where the convolution * is defined in the two-dimensional case as:

$${x}_{k}^{( n )} [ i , j ] = ( {K}_{k} * {x}^{( n - 1 )} ) [ i , j ] = {Σ}_{{i}^{′}} {Σ}_{{j}^{′}} {K}_{k} [ {i}^{′} , {j}^{′} ] \cdot {x}^{( n - 1 )} [ i - {i}^{′} , j - {j}^{′} ] .$$

Here the k-th kernel Kₖ is a d-dimensional matrix (in this embodiment a two-dimensional matrix), which is usually small compared to the number of nodes 612-620 (e.g. a 3×3 matrix, or a 5×5 matrix). In particular, this implies that the weights of the incoming edges are not independent, but chosen such that they produce said convolution equation. In particular, for a kernel being a 3×3 matrix, there are only 9 independent weights (each entry of the kernel matrix corresponding to one independent weight), irrespectively of the number of nodes 612-620 in the respective layer 602-610. In particular, for a convolutional layer 604, the number of nodes 614 in the convolutional layer is equivalent to the number of nodes 612 in the preceding layer 602 multiplied with the number of kernels.

If the nodes 612 of the preceding layer 602 are arranged as a d-dimensional matrix, using a plurality of kernels may be interpreted as adding a further dimension (denoted as “depth” dimension), so that the nodes 614 of the convolutional layer 604 are arranged as a (d+1)-dimensional matrix. If the nodes 612 of the preceding layer 602 are already arranged as a (d+1)-dimensional matrix including a depth dimension, using a plurality of kernels may be interpreted as expanding along the depth dimension, so that the nodes 614 of the convolutional layer 604 are arranged also as a (d+1)-dimensional matrix, wherein the size of the (d+1)-dimensional matrix with respect to the depth dimension is by a factor of the number of kernels larger than in the preceding layer 602.

The advantage of using convolutional layers 604 is that spatially local correlation of the input data may exploited by enforcing a local connectivity pattern between nodes of adjacent layers, in particular by each node being connected to only a small region of the nodes of the preceding layer.

In embodiment shown in FIG. 5, the input layer 602 includes 36 nodes 612, arranged as a two-dimensional 6×6 matrix. The convolutional layer 604 includes 72 nodes 614, arranged as two two-dimensional 6×6 matrices, each of the two matrices being the result of a convolution of the values of the input layer with a kernel. Equivalently, the nodes 614 of the convolutional layer 604 may be interpreted as arranges as a three-dimensional 6×6×2 matrix, wherein the last dimension is the depth dimension.

A pooling layer 606 may be characterized by the structure and the weights of the incoming edges and the activation function of its nodes 616 forming a pooling operation based on a non-linear pooling function f. For example, in the two dimensional case the values x⁽ⁿ⁾ of the nodes 616 of the pooling layer 606 may be calculated based on the values x⁽ⁿ⁻¹⁾ of the nodes 614 of the preceding layer 604 as

$${x}^{( n )} [ i , j ] = f ( {x}^{( n - 1 )} [ {id}_{1} , {jd}_{2} ] , … , {x}^{( n - 1 )} [ {id}_{1} + {d}_{1} - 1 , {jd}_{2} + {d}_{2} - 1 ] )$$

In other words, by using a pooling layer 606, the number of nodes 614, 616 may be reduced, by replacing a number d1·d2 of neighboring nodes 614 in the preceding layer 604 with a single node 616 being calculated as a function of the values of said number of neighboring nodes in the pooling layer. In particular, the pooling function f may be the max-function, the average or the L2-Norm. In particular, for a pooling layer 606 the weights of the incoming edges are fixed and are not modified by training.

The advantage of using a pooling layer 606 is that the number of nodes 614, 616 and the number of parameters is reduced. This leads to the amount of computation in the network being reduced and to a control of overfitting.

In the embodiment shown in FIG. 5, the pooling layer 606 is a max-pooling, replacing four neighboring nodes with only one node, the value being the maximum of the values of the four neighboring nodes. The max-pooling is applied to each d-dimensional matrix of the previous layer.

A fully-connected layer 608 may be characterized by the fact that a majority, in particular, all edges between nodes 616 of the previous layer 606 and the nodes 618 of the fully-connected layer 608 are present, and wherein the weight of each of the edges may be adjusted individually.

In this embodiment, the nodes 616 of the preceding layer 606 of the fully-connected layer 608 are displayed both as two-dimensional matrices, and additionally as non-related nodes (indicated as a line of nodes, wherein the number of nodes was reduced for a better presentability). In this embodiment, the number of nodes 618 in the fully connected layer 608 is equal to the number of nodes 616 in the preceding layer 606. Alternatively, the number of nodes 616, 618 may differ.

A convolutional neural network 600 may also include a ReLU (rectified linear units) layer or activation layers with non-linear transfer functions. In particular, the number of nodes and the structure of the nodes contained in a ReLU layer is equivalent to the number of nodes and the structure of the nodes contained in the preceding layer. In particular, the value of each node in the ReLU layer is calculated by applying a rectifying function to the value of the corresponding node of the preceding layer.

The input and output of different convolutional neural network blocks may be wired using summation (residual/dense neural networks), element-wise multiplication (attention) or other differentiable operators. Therefore, the convolutional neural network architecture may be nested rather than being sequential if the whole pipeline is differentiable.

In particular, convolutional neural networks 600 may be trained based on the backpropagation algorithm. For preventing overfitting, methods of regularization may be used, e.g. dropout of nodes 612-620, stochastic pooling, use of artificial data, weight decay based on the L1 or the L2 norm, or max norm constraints. Different loss functions may be combined for training the same neural network to reflect the joint training objectives. A subset of the neural network parameters may be excluded from optimization to retain the weights pretrained on another datasets.

The machine learning networks 230 are configured to input a first image and a second image and generate a displacement map/distortion map. The machine learning networks 230 may input each pair of two sets of images, for example that correspond to each axis. The output displacement maps 240/distortion maps may be combined using a linear superposition model.

As described above, the switching of spatial encoding fields, which are generated by the gradient coils, for instance, results in the induction of eddy currents in conducting structures of the magnetic resonance system, which, for their part, generate temporally decaying field disturbances. If field disturbances of this type are present during the spatial encoding, this results directly in spatial misallocations. In an embodiment, for correcting an acquired image using the generated displacement map, an individual displacement vector for each target image pixel is calculated for each target image pixel as a function of the field deviation calculated previously and applying at the position of the respective target image pixel. With the aid of this individual displacement vector, the associated actual image pixel is determined for each target image pixel. In other words, the position to which the signal portion of the target image pixel has been displaced as a result of the distortion effects taken into account is determined on the basis of the individual displacement vector for each target image pixel.

In another embodiment, dedicated diffusion encoding schemes are used that apply different gradient shapes on each axis: Gᵢ(t)=aᵢ Rᵢ (fₓ(t), f_{y}(t), f_{z}(t)). These kinds of gradient shapes have recently attracted attention, e.g. for obtaining a spherical shape of the b-tensor. Since the temporal eddy current characteristics is axis-specific, and averages of long-lasting eddy currents during the EPI module depend on their actual shape, the six adjustment scans described above may no longer be sufficient to completely characterize Eᵢ(r). However, the linear superposition model may still be applied to correct images acquired with arbitrary combinations of aᵢ and Rᵢ after characterizing eddy current fields for each shape on each axis. The spatial characteristics of the eddy current field may be decomposed as Eᵢ(r)=aᵢ Σ_{j=1,2,3}(Rᵢ êₓ Ê_{x,j}(r)+Rᵢ ê_{y} Ê_{y,j}(r)+Rᵢ ê_{z} Ê_{z,j}(r)) where Ê_{x/y/z,j}(r) represent the eddy current fields induced by a unit gradient shape fⱼ(t) along the corresponding axis ê_{x/y/z}. Characterization of Ê_{x/y/z,j}(r) requires nine pairs of images acquired with dedicated shapes, rotations and scalings (j∈{1, 2, 3}):

$$\begin{matrix}{G}_{x , j , A} ( t ) = {f}_{j} ( t ) {a}_{A , x} {\underline{R}}_{x} ( 1 , 0 , 0 ) = {f}_{j} ( t ) {a}_{A , x} {\hat{e}}_{x} , & {G}_{x , j , B} ( t ) = {f}_{j} ( t ) {a}_{B , x} {\underline{R}}_{x} ( 1 , 0 , 0 ) = {f}_{j} ( t ) {a}_{B , x} {\hat{e}}_{x} \\ {G}_{y , j , A} ( t ) = {f}_{j} ( t ) {a}_{A , y} {\underline{R}}_{y} ( 1 , 0 , 0 ) = {f}_{j} ( t ) {a}_{A , y} {\hat{e}}_{y} , & {G}_{y , j , B} ( t ) = {f}_{j} ( t ) {a}_{B , y} {\underline{R}}_{y} ( 1 , 0 , 0 ) = {f}_{j} ( t ) {a}_{B , y} {\hat{e}}_{y} \\ {G}_{z , j , A} ( t ) = {f}_{j} ( t ) {a}_{A , z} {\underline{R}}_{z} ( 1 , 0 , 0 ) = {f}_{j} ( t ) {a}_{A , z} {\hat{e}}_{z} , & {G}_{z , j , B} ( t ) = {f}_{j} ( t ) {a}_{B , z} {\underline{R}}_{z} ( 1 , 0 , 0 ) = {f}_{j} ( t ) {a}_{B , z} {\hat{e}}_{z}\end{matrix}$$

According to an embodiment, a deep learning technique uses the corresponding pairs of distorted images to generate displacement maps 240 M_{x/y/z,j}(r)=BW⁻¹ ΔE_{x/y/z}(r), and the required reference eddy current fields are obtained via Ê_{x/y/z,j}(r)=(E_{x/y/z,j,A}(r)−E_{x/y/z,j,B}(r)/(a_{A,x/y/z}−a_{B,x/y/z})=BW M_{x/y/z,j}(r)/(a_{A,x/y/z}−a_{B,x/y/z}) or, using a_{A,x}=a_{A,y}=a_{A,z}=a_{A} and a_{B,x}=a_{B,y}=a_{B,z}=−a_{A}; Ê_{x/y/z,j}(r)=(E_{x/y/z,j,A}(r)−E_{x/y/z,j,B}(r))/(2 a_{A})=BW M_{x/y/z,j}(r)/(2 a_{A}).

The processor 22 is configured to output one or more displacement maps 240 or corrected images. The one or more displacement maps 240 or corrected images may be displayed using the operator interface 26 that includes an input device and an output device. The input may be an interface, such as interfacing with a computer network, memory, database, medical image storage, or other source of input data. The input may be a user input device, such as a mouse, trackpad, keyboard, roller ball, touch pad, touch screen, or another apparatus for receiving user input. The output is a display device but may be an interface. The images and/or displacement maps 240 may be displayed. The display is a CRT, LCD, plasma, projector, printer, or other display device. The display is configured by loading an image to a display plane or buffer. The display is configured to display the image of the region of the patient. The operator interface may include a graphical user interface (GUI) enabling user interaction with the MRI system 100.

Embodiments provide high precision (capturing higher-order eddy current fields), robust estimation, and high computational performance (network evaluations can be performed very rapidly with modern hardware, e.g., GPUs).

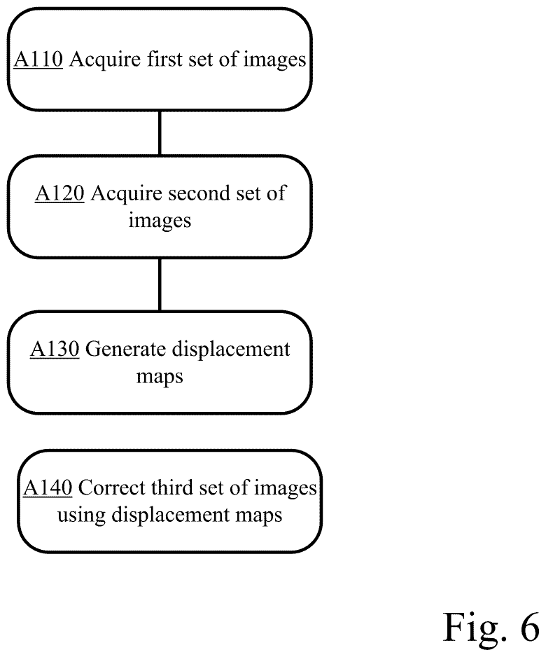

FIG. 6 depicts an example method for correction of eddy current distortions in diffusion MRI. The method is performed by the system 100 of FIG. 1 or another system. The method is performed in the order shown or other orders. Additional, different, or fewer acts may be provided. In an example, the displacement maps 240 may be generated and then used for multiple subsequent scans. Additional adjustment scans may be used to acquire additional image data for generating the displacement maps 240. Further steps such as denoising and registration may be used prior to generating the displacement maps 240.

At act A110, the MRI system 100 acquires a first set of images 210 with a first diffusion encoding. At act A120, the MRI system 100 acquires a second set of images 220 with a different diffusion encoding. The acquisition may be performed as a quick adjustment scan prior to performing an imaging scan of a patient. By running the adjustment scans immediately before acquiring the imaging data, eddy current fields which are representative for the current scan environment (e.g., position of the table within the scanner, temperature of the cryogen shields) will get captured.

At Act A130, using a pair of distorted images D_{x/y/z,A}(r) and D_{x/y/z,B}(r) as an input, machine learning network 230 generates displacement maps 240 M_{x/y/z}(r) that characterize a transformation D_{x/y/z,A}(r)->D_{x/y/z,B}(r) (or vice versa). Once Ê_{x/y/z}(r) is known it is possible to obtain an estimate of the eddy current fields for any rotation and/or scaling of the diffusion gradients. As described above, in one or more example embodiments, the machine learning network 230 may be trained using a combination of supervised and unsupervised learning. Supervised learning is generally known in the art and may include training of the neural network that involves computing loss of the neural network by comparing an output of the neural network, such as the modified images, to a ground-truth image. Thus, for each input into the neural network, there is a corresponding desired output. Unsupervised learning is similarly generally known in the art and may involve computing loss of the neural network without requiring a corresponding desired output.

In one or more example embodiments, the neural network may be at least one of a general adversarial network (GAN), a multiscale generator model architecture, a GAN multiscale generator model with attention architecture, or a GAN generator model with attention and with recurrent convolutional layers architecture. In at least one example embodiment, the neural network may be a Pix2Pix GAN basic UNet generator model architecture, a Pix2Pix GAN attention UNet generator model architecture, or a Pix2Pix GAN attention R2UNet generator model architecture.

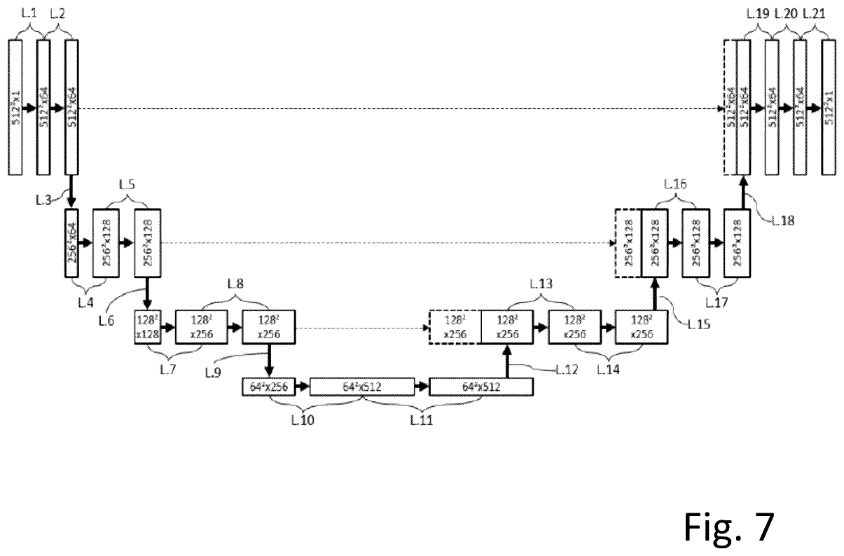

FIG. 7 depicts an example UNet architecture that may be used for the image to image network. The input data to the machine learning network 230 is a two-dimensional medical image comprising 512×512 pixel, every pixel comprising one intensity value. The machine learning network 230 comprises convolutional layers (indicated by solid, horizontal arrows), pooling layers (indicating by solid arrows pointing down), and upsampling layers (indicated by solid arrows pointing up), the number of the respective nodes is indicated within the boxes. Within the U-net structure first the input images are downsampled (decreasing the size of the im-ages and increasing the number of channels), afterwards they are upsampled (increasing the size of the images and decreasing the number of channels) to generate a transformed image.

All except the last convolutional layers L.1, L.2, L.4, L.5, L.7, L.8, L.10, L.11, L.13, L.14, L.16, L.17, L.19, L.20 use 3×3 kernels with a padding of 1, the ReLU activation function, and a number of filters/convolutional kernels that matches the number of channels of the respective node layers as indicated in FIG. 7. The last convolutional layer uses a 1×1 kernel with no padding and the ReLU activation function.

The pooling layers L.3, L.6, L.9 are max-pooling layers, replacing four neighboring nodes with only one node, the value being the maximum of the values of the four neighboring nodes. The upsampling layers L.12, L.15, L.18 are transposed convolution layers with 3×3 kernels and stride 2, which effectively quadruple the number of nodes. The dashed horizontal errors correspond to concatenation operations, where the output of a convolutional layer L.2, L.5, L.8 of the downsampling branch of the U-net structure is used as additional inputs for a convolutional layer L.13, L.16, L.19 of the upsampling branch of the U-net structure. This additional input data is treated as additional channels in the input node layer for the convolutional layer L.13, L.16, L.19 of the upsampling branch.

In one or more example embodiments, a neural network as described herein may be a Pix2Pix GAN basic UNet generator model architecture. The generator of this model architecture may include a whole image-to-image auto-encoder network with UNet skip connections to generate better image quality at higher resolutions. The Discriminator in the Pix2Pix GAN may include a PatchGAN Discriminator network that may output a classification matrix. In one or more example embodiments, a neural network as described herein may alternatively be a Pix2Pix GAN attention UNet generator model architecture. This model architecture includes at least one attention gate. The one or more attention gates may be implemented at skip connections and may actively suppress activations in irrelevant regions. This may help to reduce the number of redundant features, which may reduce the computational resources wasted on irrelevant activations. A Pix2Pix GAN attention R2UNet generator model architecture may utilize the power of UNet, Residual Network, as well as Recurrent Convolutional Neural Network (RCNN) with attention gates for the generator. In some example embodiments, the Pix2Pix GAN attention R2UNet generator model architecture may have several benefits. One benefit may be that the Pix2Pix GAN attention R2UNet generator model architecture includes a residual unit that may alleviate the problem of vanishing gradients seen in other deep learning models which may help with training deep architecture. An additional benefit may be feature accumulation with recurrent residual convolutional layers that may ensure better feature representation. Another benefit may be that the Pix2Pix GAN attention R2UNet generator model architecture may focus on the main areas of the images by using the attention gates. Each of these benefits helps to create a more stable U-Net architecture without changing the number of network parameters.

For any of the above-described model architectures, testing may be completed to evaluate the models. In at least one example embodiment, performance metrics used to evaluate the model architectures may include a structural similarity index measure (SSIM), DICE coefficient, mean absolute error (MAE), peak signal-to-noise ratio (PSNR), or Fréchet Inception Distance (FID). In at least one embodiment, hyperparameter tuning, ablation studies, and failure analysis may additionally be implemented to find limitations of any of the models. In at least one example embodiment, the loss metric that a neural network described herein is trained to reduce and/or minimize may include at least one of a discriminant loss, Wasserstein loss, or a loss computed using a pretrained (neural network) model (e.g., perceptual loss).

The output of the machine learning network 230 is one or more displacement maps 240/distortion maps that may be combined using a linear superposition. The displacement maps 240/distortion maps may be used to characterize eddy current distortions which may be used to correct subsequent image data.

At act A140, the output displacement map may be used for correcting a third set of images. The third set of images may be acquired using the MRI scanner. A correction method as described in U.S. Pat. No. 8,283,925, hereby incorporated by reference in its entirety, may be used, for example, by automatically calculating correction parameters, in each of three orthogonal diffusion directions that de-skew diffusion weighted magnetic resonance images, and making said correction parameters available at an output of the processor in a form allowing correction of a subsequently-obtained diffusion-weighted diagnostic magnetic resonance image with the correction parameters to substantially correct for image distortions arising due to the diffusion-weighting in the diagnostic magnetic resonance image. Another correction method may be used as described in U.S. Pat. No. 11,215,683, hereby incorporated by reference in its entirety, for example, where from the displacement maps 240, a respective displacement vector is calculated for each image pixel. A signal portion is assigned to each image pixel that has been displaced with the respective displacement vector from the respective image pixel. Another correction method may be used as described in U.S. Pat. No. 11,402,454, hereby incorporated by reference in its entirety, where an image distortion of an acquisition of diffusion imaging is compensated, which takes place by application of the diffusion imaging pulse sequence on the basis of the determined magnetic field deviation. Another correction method may be used as described in U.S. Pat. No. 11,215,683, hereby incorporated by reference in its entirety, where correction parameters are determined and used based on determined displacement maps 240. Another correction method may be used as described in U.S. Pat. No. 8,508,226, hereby incorporated by reference in its entirety, where correction parameters are determined and used based on determined displacement maps 240. Another correction method may be used as described in U.S. Pat. No. 8,487,617, hereby incorporated by reference in its entirety, where a deskewing function is determined as are correction parameters to deskew diffusion-weighted magnetic resonance images on the basis of the measurements, so that image information and/or correction parameters of different slices are linked with one another. The diffusion-weighted magnetic resonance images are distortion-corrected on the basis of the deskewing function and the correction parameters.

While the invention has been described above by reference to various embodiments, many changes and modifications may be made without departing from the scope of the invention. It is therefore intended that the foregoing detailed description be regarded as illustrative rather than limiting, and that it be understood that it is the following claims, including all equivalents, that are intended to define the spirit and scope of this invention. Independent of the grammatical term usage, individuals with male, female or other gender identities are included within the term. The following is a list of non-limiting illustrative embodiments disclosed herein:

Illustrative embodiment 1. A method for correction of eddy current induced distortions in diffusion MRI, the method comprising: acquiring, using a first adjustment scan, a first set of images with a first diffusion encoding; acquiring, using a second adjustment scan, a second set of images with a second diffusion encoding, the second diffusion encoding different than the first diffusion encoding; estimating, by a machine learning network, a set of spatial distortion maps based on respective pairs of images from the first set of images and the second set of images; acquiring, using a imaging scan, a third set of images with arbitrary diffusion encoding; and correcting eddy current induced distortions in the third set of images using the set of spatial distortion maps.

Illustrative embodiment 2. The method of illustrative embodiment 1, wherein estimating the set of spatial distortion maps comprises estimating, by the machine learning network, a transformation from a respective image of the first set to a paired image of the second set.

Illustrative embodiment 3. The method of illustrative embodiment 1, wherein the machine learning network comprises an image to image network.

Illustrative embodiment 4. The method of illustrative embodiment 1, further comprising: applying a registration of image pairs from the first set of images and the second set of images prior to estimating the set of spatial distortion maps.

Illustrative embodiment 5. The method of illustrative embodiment 1, further comprising: combining spatial distortion maps referring to reference eddy current fields from the respective pairs using a linear superposition model to generate spatial distortion maps referring to actual eddy current fields that are used for the correction of third set of images.

Illustrative embodiment 6. The method of illustrative embodiment 1, wherein the first adjustment scan and the second adjustment scan acquire image data for each of three axis.

Illustrative embodiment 7. The method of illustrative embodiment 6, wherein for each axis, the two adjustment scans are acquired immediately after each other in order to reduce an impact of subject motion.

Illustrative embodiment 8. The method of illustrative embodiment 1, wherein the first adjustment scan and second adjustment scan are repeated, wherein the estimation uses averaged image data from the repeated adjustment scans.

Illustrative embodiment 9. The method of illustrative embodiment 1, wherein correcting comprises: for each respective pixel in the third set of images, a signal portion of an actual image pixel, a position of which is calculated on the basis of the set of spatial distortion maps is thereby assigned in each case to the respective target image pixel.

Illustrative embodiment 10. The method of illustrative embodiment 1, wherein the adjustment scans are acquired along a same directions as used in the imaging scan.

Illustrative embodiment 11. The method of illustrative embodiment 1, wherein the diffusion encoding scheme of the imaging scan applies different gradient shapes on each axis, wherein for the adjustment scans nine pairs of images are acquired with dedicated shapes, rotations, and scalings.

Illustrative embodiment 12. A system for correction of eddy current induced distortions in diffusion MRI, the system comprising: a MRI scanner configured to acquire image data; and a control unit comprising at least a processor and a memory, the control unit configured to instruct the MRI scanner to perform a first adjustment scan to acquire a first set of imaging data, to perform a second adjustment scan to acquire a second set of imaging data, and to perform an imaging procedure on a patient to acquire a third set of imaging data, wherein the control unit is configured, using a machine learning network, to estimate one or more displacements maps from the first set of imaging data and the second set of imaging data and correct the third set of imaging data using at least the one or more displacement maps.

Illustrative embodiment 13. The system of illustrative embodiment 12, further comprising: a display configured to display the corrected third set of imaging data.

Illustrative embodiment 14. The system of illustrative embodiment 12, wherein estimating the one or more displacement maps comprises estimating, by the machine learning network comprising an image to image network, a transformation from a respective image of the first set to a paired image of the second set.

Illustrative embodiment 15. The system of illustrative embodiment 12, wherein the control unit is further configured to apply a registration of image pairs from the first set of images and the second set of images prior to estimating the one or more displacement maps in order to reduce motion.

Illustrative embodiment 16. The system of illustrative embodiment 12, further comprising: combining spatial distortion maps referring to reference eddy current fields from the respective pairs using a linear superposition model to generate spatial distortion maps referring to actual eddy current fields that are used for the correction of third set of images.

Illustrative embodiment 17. The system of illustrative embodiment 12, wherein the first adjustment scan and the second adjustment scan acquire image data for each of three axis.

Illustrative embodiment 18. The system of illustrative embodiment 17, wherein for each axis, the two adjustment scans are acquired immediately after each other in order to reduce an impact of subject motion.

Illustrative embodiment 19. The system of illustrative embodiment 12, wherein the first adjustment scan and second adjustment scan are repeated, wherein the estimation uses averaged image data from the repeated adjustment scans.

Illustrative embodiment 20. A non-transitory computer readable storage medium comprising a set of computer-readable instructions stored thereon for correction of eddy current induced distortions in diffusion MRI, the computer-readable instructions which, when executed by at least one processor cause the at least one processor to: estimate, using a machine learning network, a set of spatial distortion maps based on respective pairs of images from a first set of images from a first adjustment scan performed with a first diffusion encoding and a second set of images from a second adjustment scan performed with a second diffusion encoding, the second diffusion encoding different than the first diffusion encoding; and correct eddy current induced distortions in a third set of images using the set of spatial distortion maps.

1. A method for correction of eddy current induced distortions in diffusion MRI, the method comprising:
acquiring, using a first adjustment scan, a first set of images with a first diffusion encoding;
acquiring, using a second adjustment scan, a second set of images with a second diffusion encoding, the second diffusion encoding different than the first diffusion encoding;
estimating, by a machine learning network, a set of spatial distortion maps based on respective pairs of images from the first set of images and the second set of images;
acquiring, using a imaging scan, a third set of images with arbitrary diffusion encoding; and
correcting eddy current induced distortions in the third set of images using the set of spatial distortion maps.

2. The method of claim 1, wherein estimating the set of spatial distortion maps comprises estimating, by the machine learning network, a transformation from a respective image of the first set to a paired image of the second set.

3. The method of claim 1, wherein the machine learning network comprises an image to image network.

4. The method of claim 1, further comprising:
applying a registration of image pairs from the first set of images and the second set of images prior to estimating the set of spatial distortion maps.

5. The method of claim 1, further comprising:
combining spatial distortion maps referring to reference eddy current fields from the respective pairs using a linear superposition model to generate spatial distortion maps referring to actual eddy current fields that are used for the correction of third set of images.

6. The method of claim 1, wherein the first adjustment scan and the second adjustment scan acquire image data for each of three axis.

7. The method of claim 6, wherein for each axis, the two adjustment scans are acquired immediately after each other in order to reduce an impact of subject motion.

8. The method of claim 1, wherein the first adjustment scan and second adjustment scan are repeated, wherein the estimation uses averaged image data from the repeated adjustment scans.

9. The method of claim 1, wherein correcting comprises:
for each respective pixel in the third set of images, a signal portion of an actual image pixel, a position of which is calculated on the basis of the set of spatial distortion maps is thereby assigned in each case to the respective target image pixel.

10. The method of claim 1, wherein the adjustment scans are acquired along a same directions as used in the imaging scan.

11. The method of claim 1, wherein the diffusion encoding scheme of the imaging scan applies different gradient shapes on each axis, wherein for the adjustment scans nine pairs of images are acquired with dedicated shapes, rotations, and scalings.

12. A system for correction of eddy current induced distortions in diffusion MRI, the system comprising:
a MRI scanner configured to acquire image data; and
a control unit comprising at least a processor and a memory, the control unit configured to instruct the MRI scanner to perform a first adjustment scan to acquire a first set of imaging data, to perform a second adjustment scan to acquire a second set of imaging data, and to perform an imaging procedure on a patient to acquire a third set of imaging data, wherein the control unit is configured, using a machine learning network, to estimate one or more displacements maps from the first set of imaging data and the second set of imaging data and correct the third set of imaging data using at least the one or more displacement maps.

13. The system of claim 12, further comprising:
a display configured to display the corrected third set of imaging data.

14. The system of claim 12, wherein estimating the one or more displacement maps comprises estimating, by the machine learning network comprising an image to image network, a transformation from a respective image of the first set to a paired image of the second set.

15. The system of claim 12, wherein the control unit is further configured to apply a registration of image pairs from the first set of images and the second set of images prior to estimating the one or more displacement maps in order to reduce motion.

16. The system of claim 12, further comprising: combining spatial distortion maps referring to reference eddy current fields from the respective pairs using a linear superposition model to generate spatial distortion maps referring to actual eddy current fields that are used for the correction of third set of images.

17. The system of claim 12, wherein the first adjustment scan and the second adjustment scan acquire image data for each of three axis.

18. The system of claim 17, wherein for each axis, the two adjustment scans are acquired immediately after each other in order to reduce an impact of subject motion.

19. The system of claim 12, wherein the first adjustment scan and second adjustment scan are repeated, wherein the estimation uses averaged image data from the repeated adjustment scans.

20. A non-transitory computer readable storage medium comprising a set of computer-readable instructions stored thereon for correction of eddy current induced distortions in diffusion MRI, the computer-readable instructions which, when executed by at least one processor cause the at least one processor to:
estimate, using a machine learning network, a set of spatial distortion maps based on respective pairs of images from a first set of images from a first adjustment scan performed with a first diffusion encoding and a second set of images from a second adjustment scan performed with a second diffusion encoding, the second diffusion encoding different than the first diffusion encoding; and
correct eddy current induced distortions in a third set of images using the set of spatial distortion maps.
